(19) United States
(12) Patent Application Publication
(10) Pub. No.: US 2026/0194809 A1
(43) Pub. Date: Jul. 9, 2026

(54) SUBSTRATE, METHOD FOR MANUFACTURING SUBSTRATE FOR MANUFACTURING SEMICONDUCTOR, AND METHOD FOR MANUFACTURING SEMICONDUCTOR SUBSTRATE

(71) Applicant: JSR CORPORATION, Tokyo (JP)

(72) Inventors: Shuhei YAMADA, Tokyo (JP); Eiji YONEDA, Tokyo (JP)

(73) Assignee: JSR CORPORATION, Tokyo (JP)

(21) Appl. No.: 19/550,454

(22) Filed: Feb. 26, 2026

Related U.S. Application Data
(63) Continuation-in-part of application No. PCT/JP2024/031111, filed on Aug. 30, 2024.

(30) Foreign Application Priority Data
Sep. 7, 2023 (JP) 2023-145291

(51) Int. Cl. G03F 7/004; G03F 7/16; G03F 7/20; H10P 14/68; H10P 76/20

(52) U.S. Cl. CPC G03F 7/0043; G03F 7/167; G03F 7/2004; H10P 14/683; H10P 76/2041

(57) ABSTRACT

A substrate includes: a substrate having a thin film on a surface thereof. The thin film includes a group derived from a compound represented by formula (1). In the formula (1), R¹ is an n-valent organic group having 1 to 40 carbon atoms, and n is an integer of 1 to 4.

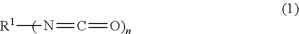

### CROSS-REFERENCE TO RELATED APPLICATIONS

The present application is a continuation-in-part application of International Patent Application No. PCT/JP2024/031111 filed Aug. 30, 2024, which claims priority to Japanese Patent Application No. 2023-145291 filed Sep. 7, 2023. The contents of these applications are incorporated herein by reference in their entirety.

### BACKGROUND OF THE DISCLOSURE

### Technical Field

The present disclosure relates to a substrate, a method for manufacturing a substrate for manufacturing a semiconductor, and a method for manufacturing a semiconductor substrate.

### Background Art

For pattern formation in the manufacture of semiconductor substrates, for example, a multilayer resist process or the like is used in which a patterned substrate is formed by etching using, as a mask, a resist pattern obtained by exposing and developing a resist film laminated on a substrate via an organic underlayer film, a silicon-containing film, and the like (WO2022/260154).

In recent years, highly enhanced integration of semiconductor devices has further advanced, and exposure light to be used tends to have a shorter wavelength, as from a KrF excimer laser beam (248 nm) or an ArF excimer laser beam (193 nm) to an extreme ultraviolet ray (13.5 nm; hereinafter also referred to as “EUV”). As the resist pattern formed by such a technique is thinned or narrowed, the resist underlayer film is also required to be thinned. A technique for forming a thin film on a silicon wafer by silane coupling treatment in a gas phase has been proposed (see JP-A-2014-74731).

### SUMMARY

According to an aspect of the present disclosure, a substrate includes: a substrate having a thin film on a surface thereof. The thin film includes a group derived from a compound represented by formula (1) (hereinafter, also referred to as “compound [A]”). In the formula (1), R¹ is an n-valent organic group having 1 to 40 carbon atoms, and n is an integer of 1 to 4.

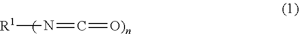

According to another aspect of the present disclosure, a method for manufacturing a substrate for manufacturing a semiconductor, includes: bringing a substrate and a compound represented by formula (1) into contact to produce the substrate for manufacturing a semiconductor.

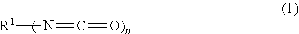

In the formula (1), R¹ is an n-valent organic group having 1 to 40 carbon atoms, and n is an integer of 1 to 4.

According to a further aspect of the present disclosure, a method for manufacturing a semiconductor substrate, includes: forming a resist film on the substrate for manufacturing a semiconductor obtained by the above-described method; exposing the resist film to radiation; and developing at least the exposed resist film.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

While thinning and narrowing of a resist pattern are progressing, a thin film as a resist underlayer film is required to have a resist pattern collapse suppression property.

The substrate for manufacturing a semiconductor of the present disclosure is excellent in resist pattern collapse suppression property. According to the method for manufacturing a substrate for manufacturing a semiconductor of the present disclosure, it is possible to manufacture a substrate for manufacturing a semiconductor excellent in resist pattern collapse suppression property. According to the method for manufacturing a semiconductor substrate of the present disclosure, since the substrate for manufacturing a semiconductor capable of exhibiting excellent pattern collapse suppression property is used, a high-quality semiconductor substrate can be efficiently manufactured. Accordingly, the substrate and methods of the present disclosure can suitably be used for, for example, manufacturing semiconductor devices expected to be further microfabricated in the future.

Hereinafter, a detailed description is made of a substrate for manufacturing a semiconductor, a method for manufacturing a substrate for manufacturing a semiconductor, and a method for manufacturing a semiconductor substrate according to each embodiment of the present disclosure. Combinations of suitable aspects in embodiments are also preferred.

### <<Substrate for Manufacturing Semiconductor>>

The substrate for manufacturing a semiconductor includes a substrate having a thin film. The thin film has a group derived from the compound [A].

### (Substrate)

The substrate is not particularly limited as long as the substrate is an object capable of forming on the surface thereof a thin film having a group derived from the compound [A]. Examples of the substrate include metallic or semimetallic substrates such as a silicon substrate, an aluminum substrate, a nickel substrate, a chromium substrate, a molybdenum substrate, a tungsten substrate, a copper substrate, a tantalum substrate, and a titanium substrate. Among them, a silicon substrate is preferable. On the substrate, an inorganic film or an organic film may be formed. Examples of the inorganic film include a silicon nitride film, an alumina film, a SiO₂ film formed by CVD, a TiON film, a SiON film, a SiOC film, a carbon hardmask (amorphous carbon film), a tantalum nitride film, a titanium nitride film, and a spin-on-glass (SOG) film. Examples of the organic film include an antireflection film.

The surface of the substrate may be a flat surface or may have a three-dimensional structure such as a trench structure.

It is preferable that at least one polar group selected from the group consisting of —OH, —SH, and —NR₂ (Rs are each independently a hydrogen atom or a monovalent hydrocarbon group having 1 to 5 carbon atoms) be present on the outermost layer of the substrate, and it is more preferable that-OH be present. As described later, a thin film having a group derived from the compound [A] is formed on the surface of the substrate by bringing the compound [A] into contact with the surface of the substrate and further chemically reacting the compound [A]. At that time, by introducing the polar group into the outermost layer of the substrate, the chemical reaction with the isocyanate group of the compound [A] can proceed, and thin film formation can be efficiently performed.

The substrate is preferably surface-treated in advance. Examples of the surface treatment include washing with an organic solvent and treatment with UV ozone. The surface treatment is preferably UV ozone treatment. This makes it possible to suitably introduce the polar group into the substrate surface.

### (Thin Film)

The thin film has a group derived from the compound [A]. The method for introducing the group derived from the compound [A] into the thin film is not particularly limited, but it is preferable that the thin film be a film produced by a gas phase reaction between the compound represented by the formula (1) and the substrate. By utilizing the gas phase reaction, an extremely thin film of a monomolecular film level can be formed in which the introduction rate of the group derived from the compound [A] can be increased, and the variation in film thickness is reduced.

The upper limit of the film thickness of the thin film is preferably 2.5 nm, more preferably 2.2 nm, still more preferably 2 nm, particularly preferably 1.8 nm. The lower limit of the film thickness is preferably 0.8 nm, more preferably 1 nm, still more preferably 1.2 nm.

### (Compound [A])

The compound [A] is a compound represented by formula (1). The compound [A] does not contain a silicon atom.

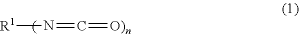

In the formula (1), R¹ is an n-valent organic group having 1 to 40 carbon atoms. n is an integer of 1 to 4.

Examples of the n-valent organic group having 1 to 40 carbon atoms represented by R¹ include a group obtained by removing n-1 hydrogen atoms from a monovalent organic group having 1 to 40 carbon atoms. Examples of the monovalent organic group having 1 to 40 carbon atoms include a monovalent hydrocarbon group having 1 to 40 carbon atoms, a group containing a divalent heteroatom-containing linking group between two carbon atoms of the foregoing hydrocarbon group, a group obtained by replacing some or all of the hydrogen atoms of the foregoing hydrocarbon group with a monovalent heteroatom-containing substituent, and a combination thereof. R¹ does not contain a silicon atom.

Examples of the monovalent hydrocarbon group having 1 to 40 carbon atoms include a monovalent chain hydrocarbon group having 1 to 40 carbon atoms, a monovalent alicyclic hydrocarbon group having 3 to 40 carbon atoms, a monovalent aromatic hydrocarbon group having 6 to 40 carbon atoms, or a combination thereof.

Examples of the monovalent chain hydrocarbon group having 1 to 40 carbon atoms include: alkyl groups such as a methyl group, an ethyl group, an n-propyl group, an isopropyl group, an n-butyl group, a sec-butyl group, and a tert-butyl group; alkenyl groups such as an ethenyl group, a propenyl group, and a butenyl group; and alkynyl groups such as an ethynyl group, a propynyl group, and a butynyl group.

Examples of the monovalent alicyclic hydrocarbon group having 3 to 40 carbon atoms include: cycloalkyl groups such as a cyclopentyl group and a cyclohexyl group; cycloalkenyl groups such as a cyclopropenyl group, a cyclopentenyl group, and a cyclohexenyl group; bridged cyclic saturated hydrocarbon groups such as a norbornyl group, an adamantyl group, and a tricyclodecyl group; and bridged cyclic unsaturated hydrocarbon groups such as a norbornenyl group and a tricyclodecenyl group.

Examples of the monovalent aromatic hydrocarbon group having 6 to 40 carbon atoms include a phenyl group, a tolyl group, a naphthyl group, an anthracenyl group, and a pyrenyl group.

Examples of the heteroatom that constitutes the divalent heteroatom-containing linking group or the monovalent heteroatom-containing substituent include an oxygen atom, a nitrogen atom, a sulfur atom, a phosphorus atom, and a halogen atom. Examples of the halogen atom include a fluorine atom, a chlorine atom, a bromine atom, and an iodine atom.

Examples of the divalent heteroatom-containing linking group include —CO—, —CS—, —NR′—, —O—, —S—, —SO₂—, or a group obtained by combining them. R′ is a hydrogen atom or a hydrocarbon group having 1 to 10 carbon atoms.

Examples of the monovalent heteroatom-containing substituent include a hydroxy group, a sulfanyl group, a cyano group, a nitro group, and a halogen atom. Examples of the halogen atom include a fluorine atom, a chlorine atom, a bromine atom, and an iodine atom.

The organic group preferably contains a hetero atom or an unsaturated bond. When the organic group appearing on the surface of the thin film on the side opposite to the substrate has such a structure, interaction with the resist film or the resist pattern is improved, so that excellent pattern collapse suppression property can be exhibited.

n is preferably an integer of 1 to 3, more preferably 1 or 2, still more preferably 1.

Specific examples of the compound [A] include compounds represented by formulas (1-1) to (1-24).

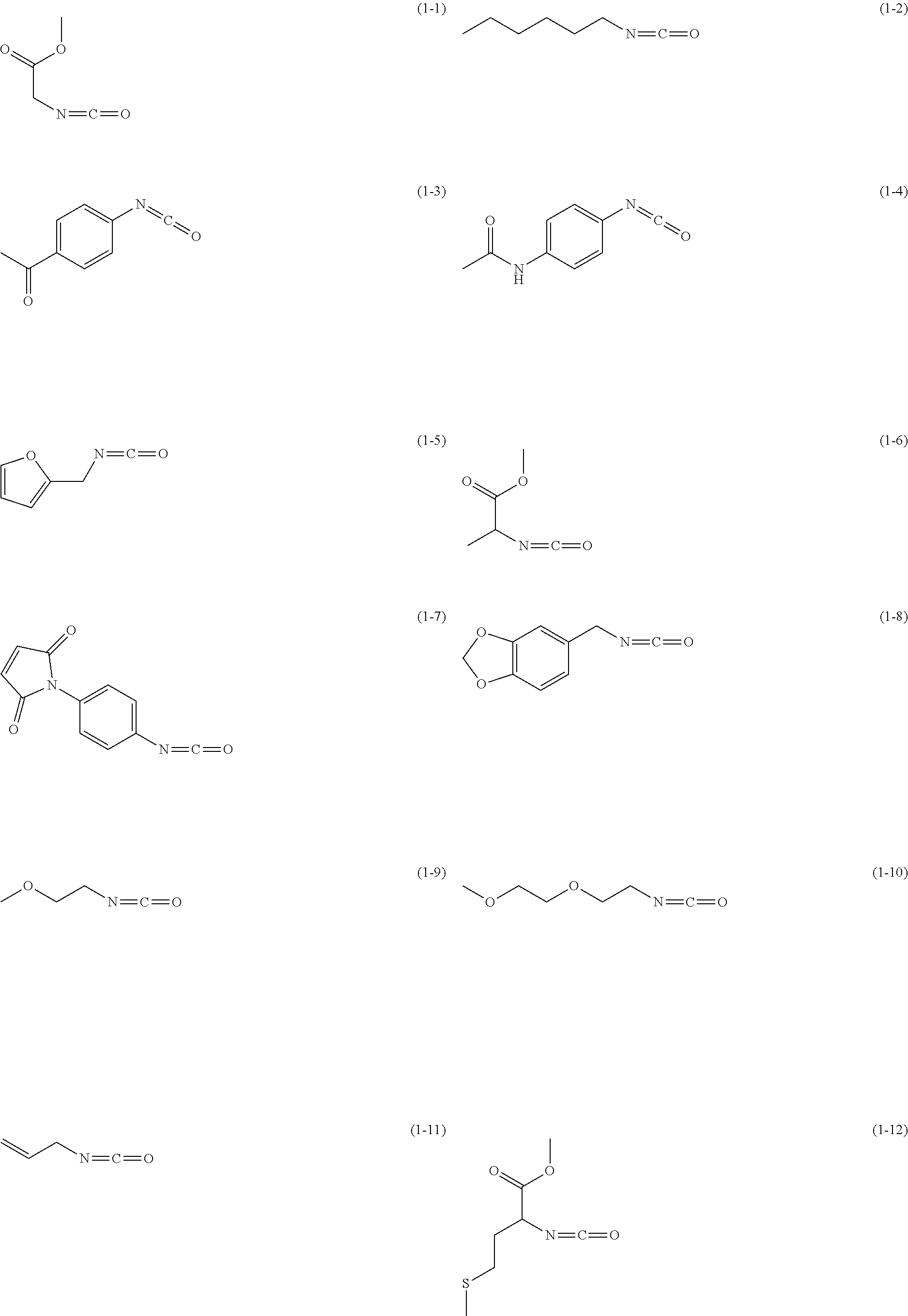

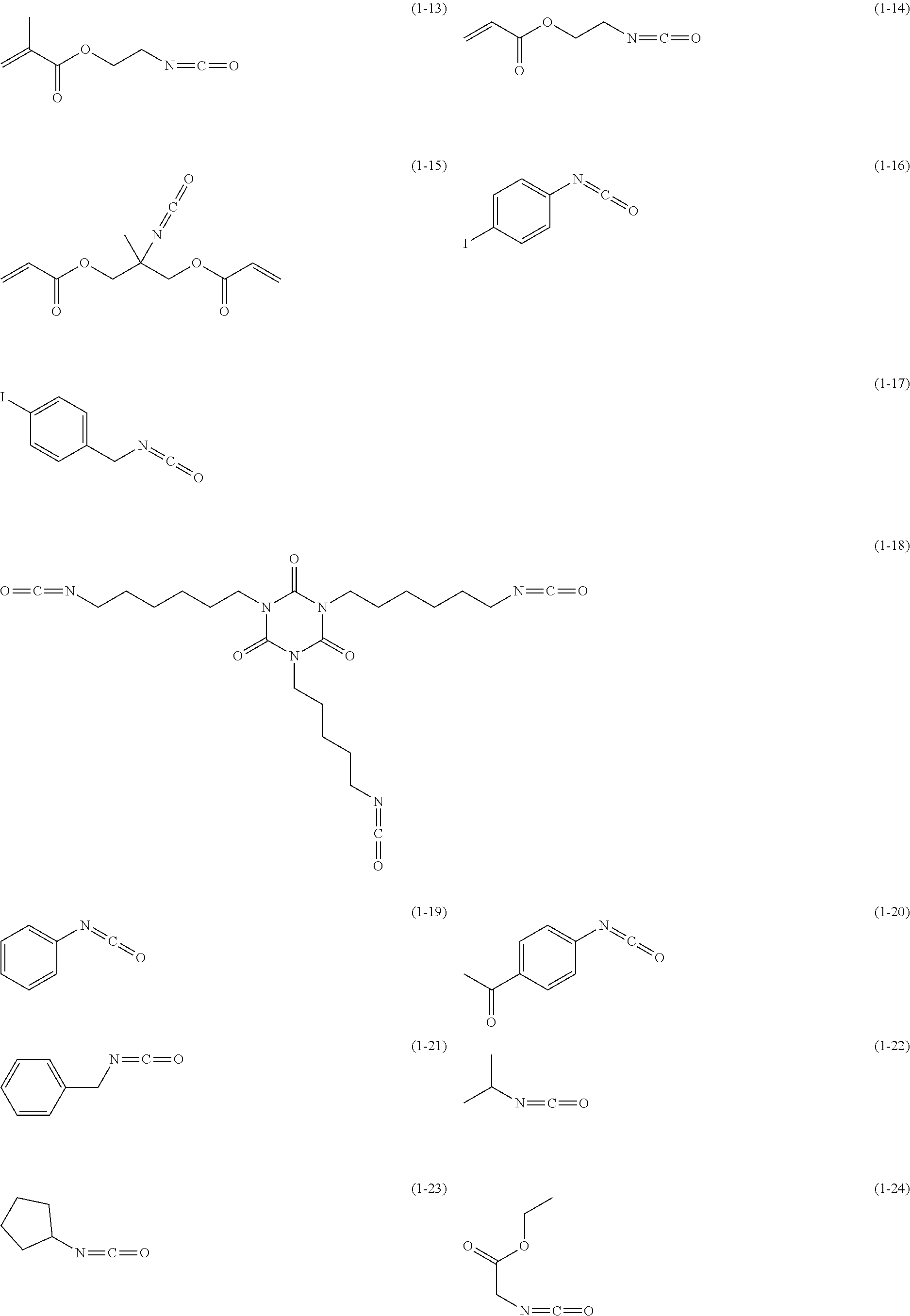

The compound [A] may be a commercially available product or a synthesized product.

### (Application of Substrate for Manufacturing Semiconductor)

The application of the substrate for manufacturing a semiconductor is not particularly limited as long as the substrate is for manufacturing a semiconductor, and may be appropriately determined. For example, the substrate is suitable as a substrate having a thin film for use in a process for manufacturing a semiconductor such as a resist underlayer film, an antireflection film, a photoelectron beam reactive resist film, or a self-assembled film. Among them, the substrate for manufacturing a semiconductor is preferably used for photolithography, more preferably used for EUV lithography, from the viewpoint that it is easy to control the interaction between the thin film and the resist film, and the thin film has a uniform film thickness of a monolayer film level.

### <<Method for Manufacturing Substrate for Manufacturing Semiconductor>>

The method for manufacturing a substrate for manufacturing a semiconductor includes bringing a substrate and a compound represented by formula (1) into contact (hereinafter also referred to as “contact step”).

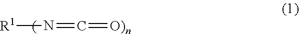

In the formula (1), R¹ is an n-valent organic group having 1 to 40 carbon atoms. n is an integer of 1 to 4.

The method for manufacturing a substrate for manufacturing a semiconductor preferably includes vaporizing the compound represented by the formula (1) (hereinafter also referred to as “vaporizing step”) before the contact step.

The method for manufacturing a substrate for manufacturing a semiconductor may include washing the substrate (hereinafter also referred to as “washing step”) after the contact step.

Hereinafter, a description is made of each step of the method for manufacturing a substrate for manufacturing a semiconductor including a vaporizing step which is a preferred step and a washing step which is an optional step. As the compound represented by the formula (1), the compound [A] described in the substrate for manufacturing a semiconductor can be suitably employed.

### (Vaporizing Step)

In this step, the compound [A] is vaporized before the contact step. The compound [A] may be a liquid or a solid at normal temperature and under normal pressure.

The method for vaporizing the compound [A] is not particularly limited, and examples thereof include heating a raw material storage container containing the compound [A], reducing the pressure in the raw material storage container containing the compound [A], or a combination thereof. The compound [A] may be vaporized using a vaporizing chamber instead of the raw material storage container. The sizes, materials, and structures of the raw material storage container and the vaporizing chamber are not particularly limited, and may be appropriately determined in consideration of the heating temperature and the degree of pressure reduction.

The heating temperature is not particularly limited. The lower limit of the heating temperature is preferably 30° C., more preferably 35° C., still more preferably 40° C. The upper limit of the heating temperature is preferably 150° C., more preferably 100° C., still more preferably 70° C.

The pressure at the time of pressure reduction is not particularly limited.

When the compound [A] is vaporized, the compound [A] itself may be vaporized, or a solution obtained by dissolving the compound [A] in an organic solvent may be vaporized. The organic solvent is not particularly limited, and examples thereof include an ester-based solvent, an ether-based solvent, and a hydrocarbon-based solvent.

Examples of the ester-based solvents include carbonate-based solvents such as diethyl carbonate; acetic acid monoacetate ester-based solvents such as methyl acetate, ethyl acetate, and butyl acetate; lactone-based solvents such as γ-butyrolactone; polyhydric alcohol partial ether carboxylate-based solvents such as diethylene glycol monomethyl ether acetate and propylene glycol monomethyl ether acetate; and lactic acid ester-based solvents such as methyl lactate and ethyl lactate.

Examples of the ether-based solvent include polyhydric alcohol ether-based solvents such as chain ether-based solvents such as n-butyl ether and cyclic ether-based solvents such as tetrahydrofuran, and polyhydric alcohol partial ether-based solvents such as diethylene glycol monomethyl ether and propylene glycol monomethyl ether.

Examples of the hydrocarbon-based solvent include aliphatic hydrocarbon-based solvents such as n-pentane, n-hexane, and cyclohexane, and aromatic hydrocarbon-based solvents such as benzene, toluene, and xylene.

The vaporized compound [A] is introduced into, for example, a film forming chamber in order to be subjected to the contact step. The method for introducing the vaporized compound [A] into the film forming chamber is not particularly limited, and examples thereof include a method in which the vaporized compound [A] is directly circulated in the film forming chamber, and a method in which the compound [A] is circulated in the film forming chamber together with a carrier gas such as argon, nitrogen, and helium.

### (Contact Step)

In this step, the substrate and the compound [A] are brought into contact with each other. The substrate is placed, for example, in a film forming chamber. Bringing the compound [A] circulated in the film forming chamber into contact with the substrate can generate a chemical reaction of the compound [A] on the surface of the substrate to form a thin film having a group derived from the compound [A] on the surface of the substrate. In an example of the chemical reaction, when n in the formula (1) is 1 and the polar group present on the substrate surface is —OH, an R¹—N(H)—(C═O)—O— group can be formed on the substrate surface by a urethane bond formation reaction between —OH and —N═C═O of the compound [A].

From the viewpoint of promoting formation of a thin film when the vaporized compound [A] is brought into contact with the surface of the substrate, the inside of the film forming chamber is preferably heated. The lower limit of the temperature in the film forming chamber is preferably 50° C., more preferably 70° C., still more preferably 80° C. The upper limit of the temperature is preferably 150° C., more preferably 130° C., still more preferably 120° C.

When the pressure in the film forming chamber is reduced in the contact step, the lower limit of the pressure is preferably 1.0×10⁻³ Pa, more preferably 4.0×10⁻³ Pa, still more preferably 8.0×10⁻³ Pa. The lower limit of the pressure is preferably 1.0×10⁻¹ Pa, more preferably 6.0×10⁻² Pa, still more preferably 2.0×10⁻² Pa.

The contact time between the substrate and the compound [A] may be appropriately set in consideration of the intended film thickness of the thin film. The lower limit of the contact time is preferably 10 seconds, more preferably 20 seconds, still more preferably 30 seconds. The upper limit of the contact time is preferably 1000 seconds, more preferably 600 seconds, still more preferably 300 seconds.

### (Washing Step)

In this step, the substrate is washed after the contact step. When the compound [A] and the substrate are further brought into contact with each other after a thin film having a group derived from the compound [A] is formed on the substrate, the compound [A] may adhere to the thin film without the chemical reaction to form a pseudo thin film. Such a pseudo thin film has low adhesion to the substrate, and thus may cause collapse of the resist pattern when the resist pattern is formed. By providing the washing step after the contact step, the excessive compound [A] on the thin film and the pseudo thin film can be removed, so that the resist pattern collapse suppression property can be improved.

The washing method is not particularly limited, but washing with a solvent is preferable. Examples of the washing method include a method for casting a solvent on a substrate having a thin film and a method for immersing a substrate having a thin film in a solvent.

As the solvent, the organic solvent that can be used at the time of vaporization of the compound [A] can be suitably employed. Among them, an ester-based solvent, an ether-based solvent, or a mixture thereof is preferable, propylene glycol monomethyl ether acetate, propylene glycol monomethyl ether, or a mixture thereof is more preferable, and a mixture of propylene glycol monomethyl ether acetate and propylene glycol monomethyl ether is still more preferable.

After the washing step, the substrate for manufacturing a semiconductor can be manufactured by providing a drying step as necessary.

### <<Method for Manufacturing Semiconductor Substrate>>

The method for manufacturing a semiconductor substrate includes a step (hereinafter, also referred to as a “resist film forming step”) of forming a resist film on the substrate for manufacturing a semiconductor obtained by the method for manufacturing a substrate for manufacturing a semiconductor, a step (hereinafter, also referred to as an “exposing step”) of exposing the resist film to radiation, and a step (hereinafter, also referred to as a “developing step”) of developing at least the exposed resist film.

### [Resist Film Forming Step]

In this step, a resist film is formed on the substrate for manufacturing a semiconductor obtained by the method for manufacturing a substrate for manufacturing a semiconductor. The resist film may be either a coating film or a deposited film, but is preferably a coating film.

Examples of the composition for forming a resist film to be used in this step include a positive or negative chemically amplified resist composition containing a radiation-sensitive acid generator, a positive resist composition containing an alkali-soluble resin and a quinonediazide-based photosensitizer, a negative resist composition containing an alkali-soluble resin and a crosslinking agent, and a composition for forming a metal-containing resist film containing a metal such as tin, zirconium, or hafnium.

The resist film preferably contains a metal. Such a metal-containing resist film is preferably formed from a composition for forming a metal-containing resist film.

### (Composition for Forming Metal-Containing Resist Film)

The composition for forming a metal-containing resist film contains a metal-containing compound (hereinafter also referred to as “metal-containing compound (A)”) and a solvent (hereinafter also referred to as “solvent (F)”), and the content ratio of the metal-containing compound (A) to components other than the solvent (F) in the composition for forming a metal-containing resist film is preferably 50% by mass or more. The composition for forming a metal-containing resist film may further contain other components.

### (Metal-Containing Compound (A))

The metal-containing compound (A) is a compound containing a metal atom. The metal-containing compound (A) may be used singly or in combination of two or more kinds thereof. In addition, the metal atom constituting the metal-containing compound (A) may be used singly or in combination of two or more kinds thereof. Here, the “metal atom” is a concept including a metalloid, that is, boron, silicon, germanium, arsenic, antimony, and tellurium.

The metal atom constituting the metal-containing compound (A) is not particularly limited. Examples thereof include metal atoms of Groups 3 to 16. Specific examples of the metal atom include a metal atom of Group 4 such as titanium, zirconium, and hafnium; a metal atom of Group 5 such as tantalum; a metal atom of Group 6 such as chromium and tungsten; a metal atom of Group 8 such as iron and ruthenium; a metal atom of Group 9 such as cobalt; a metal atom of Group 10 such as nickel; a metal atom of Group 11 such as copper; a metal atom of Group 12 such as zinc, cadmium, and mercury; a metal atom of Group 13 such as boron, aluminum, gallium, indium, and thallium; a metal atom of Group 14 such as germanium, tin, and lead; a metal atom of Group 15 such as antimony and bismuth; and a metal atom of Group 16 such as tellurium.

The metal atom constituting the metal-containing compound (A) preferably includes a first metal atom belonging to Group 4, Group 12, or Group 14 and belonging to Period 4, Period 5, or Period 6 in the periodic table. That is, the metal atom preferably contains at least one of titanium, zirconium, hafnium, zinc, cadmium, mercury, germanium, tin, and lead. As described above, the metal-containing compound (A) contains the first metal atom to further promote the release of secondary electrons in the exposed portion of the resist film and the change in solubility of the metal-containing compound (A) in a developer due to the secondary electrons and the like. As a result, the pattern rectangularity can be improved. The first metal atom is preferably tin or zirconium.

The metal-containing compound (A) preferably further has an atom other than the metal atom. Examples of the other atom include a carbon atom, a hydrogen atom, an oxygen atom, a nitrogen atom, a phosphorus atom, a sulfur atom, and a halogen atom. Among these atoms, a carbon atom, a hydrogen atom, and an oxygen atom are preferable. The other atom in the metal-containing compound (A) can be used singly or in combination of two or more kinds thereof.

In the composition for forming a metal-containing resist film, the lower limit of the content of the metal-containing compound (A) in terms of solid components is preferably 70% by mass, more preferably 90% by mass, and still more preferably 95% by mass. The content may be 100% by mass. Here, the solid components in the composition for forming a metal-containing resist film refer to components other than the solvent (F) described later.

### (Synthesis Method of Metal-Containing Compound (A))

The metal-containing compound (A) can be obtained, for example, by a method of performing a hydrolysis condensation reaction, a ligand exchange reaction, or the like on a metal compound having a metal atom and a hydrolyzable group, a hydrolysate of the metal compound, a hydrolysis condensation product of the metal compound, or a combination thereof. The metal compound can be used singly or in combination of two or more kinds thereof.

The metal-containing compound (A) is preferably derived from a metal compound having a metal atom and a hydrolyzable group and represented by formula (4) (hereinafter, also referred to as a “metal compound precursor (1)”). By using such a metal compound precursor (1), a stable metal-containing compound (A) can be obtained.

Lₐ₁^{A}MY_{b1} (4)

In the formula (4), M is a metal atom; L^{A} is a ligand or a monovalent organic group having 1 to 20 carbon atoms; a1 is an integer of 0 to 6; when a1 is 2 or more, the plurality of L¹s may be the same or different from each other; Y is a monovalent hydrolyzable group; b1 is an integer of 2 to 6; the plurality of Ys may be the same or different from each other; and L^{A} is a ligand or an organic group that is not Y.

As used herein, “organic group” means a group containing at least one carbon atom, and “carbon number” means the number of carbon atoms constituting the group.

The metal atom represented by M is preferably metal atoms of Group 14, and more preferably tin.

The hydrolyzable group represented by Y can be appropriately changed according to the metal atom represented by M. Examples thereof include a substituted or unsubstituted ethynyl group, a halogen atom, an alkoxy group, an acyloxy group, and a substituted or unsubstituted amino group.

As the substituent in the substituted or unsubstituted ethynyl group and the substituted or unsubstituted amino group represented by Y, a monovalent hydrocarbon group having 1 to 20 carbon atoms is preferable, a chain hydrocarbon group is more preferable, and an alkyl group is still more preferable.

Examples of the halogen atom represented by Y include a fluorine atom, a chlorine atom, a bromine atom, and an iodine atom. Among them, a chlorine atom is preferable.

Examples of the alkoxy group represented by Y include a methoxy group, an ethoxy group, a n-propoxy group, an i-propoxy group, and a n-butoxy group. Among them, an ethoxy group, an i-propoxy group, and a n-butoxy group are preferable.

Examples of the acyloxy group represented by Y include a formyl group, an acetoxy group, an ethyryloxy group, a propionyloxy group, a n-butyryloxy group, a t-butyryloxy group, a t-amyryloxy group, a n-hexanecarbonyloxy group, and a n-octanecarbonyloxy group. Among them, an acetoxy group is preferable.

Examples of the substituted or unsubstituted amino group represented by Y include an amino group, a methylamino group, a dimethylamino group, a diethylamino group, and a dipropylamino group. Among them, a dimethylamino group and a diethylamino group are preferable.

Hereinafter, preferred combinations of the metal atom represented by M and the hydrolyzable group represented by Y will be described. When the metal atom represented by M is tin, the hydrolyzable group represented by Y is preferably a substituted or unsubstituted ethynyl group, a halogen atom, an alkoxy group, an acyloxy group, and a substituted or unsubstituted amino group, and more preferably a halogen atom. When the metal atom represented by M is germanium, the hydrolyzable group represented by Y is preferably a halogen atom, an alkoxy group, an acyloxy group, and a substituted or unsubstituted amino group. When the metal atom represented by M is hafnium, zirconium, and titanium, the hydrolyzable group represented by Y is preferably a halogen atom, an alkoxy group, and an acyloxy group.

Examples of the ligand represented by L^{A} include a monodentate ligand and a multidentate ligand.

Examples of the monodentate ligand include a hydroxo ligand, a nitro ligand, and ammonia.

Examples of the multidentate ligand include a hydroxy acid ester, a β-diketone, a β-ketoester, a malonic acid diester in which a carbon atom at the α-position is optionally substituted, a hydrocarbon having a n bond, a ligand derived from these compounds, and a diphosphine.

Examples of the hydroxy acid esters include glycolic acid esters, lactic acid esters, 2-hydroxycyclohexane-1-carboxylic acid esters, and salicylic acid esters.

Examples of the β-diketones include 2, 4-pentanedione, 3-methyl-2, 4-pentanedione, and 3-ethyl-2, 4-pentanedione.

Examples of the β-ketoesters include acetoacetic acid esters, α-alkyl-substituted acetoacetic acid esters, β-ketopentanoic acid esters, benzoylacetic acid esters, and 1, 3-acetonedicarboxylic acid esters.

Examples of the β-dicarboxylic acid esters include malonic diesters, α-alkyl-substituted malonic diesters, α-cycloalkyl-substituted malonic diesters, and α-aryl-substituted malonic diesters.

Examples of the hydrocarbons having a π bond include
chain olefins such as ethylene and propylene;
cyclic olefins such as cyclopentene, cyclohexene, and norbornene;
chain dienes such as butadiene and isoprene;
cyclic dienes such as cyclopentadiene, methylcyclopentadiene, pentamethylcyclopentadiene, cyclohexadiene, and norbornadiene; and
aromatic hydrocarbons such as benzene, toluene, xylene, hexamethylbenzene, naphthalene, and indene.

Examples of the diphosphine include 1,1-bis(diphenylphosphino) methane, 1,2-bis(diphenylphosphino) ethane, 1,3-bis(diphenylphosphino) propane, 2, 2′-bis(diphenylphosphino)-1, 1′-binaphthyl, and 1, 1′-bis(diphenylphosphino) ferrocene.

As the monovalent organic group represented by L^{A}, groups corresponding to 1 to 20 carbon atoms among the monovalent organic groups having 1 to 40 carbon atoms represented by R¹ of the formula (1) can be suitably employed.

Examples of the monovalent organic group represented by L^{A} include groups similar to the groups exemplified as the monovalent organic group having 1 to 20 carbon atoms represented by Y in the formula (1-1) and the formula (1-2).

The lower limit of the carbon number in the monovalent organic group represented by L¹ is preferably 2, and more preferably 3. On the other hand, the upper limit of the carbon number is preferably 10, and more preferably 5. The monovalent organic group represented by L¹ is preferably a substituted or unsubstituted hydrocarbon group, more preferably a substituted or unsubstituted chain hydrocarbon group or a substituted or unsubstituted aromatic hydrocarbon group, still more preferably a substituted or unsubstituted alkyl group or a substituted or unsubstituted aralkyl group, and particularly preferably an isopropyl group or a benzyl group.

a1 is preferably 1 or 2, and more preferably 1.

b1 is preferably an integer of 2 to 4. By setting b1 to the above numerical value, the content ratio of the metal atom in the metal-containing compound (A) can be increased, and the generation of secondary electrons by the metal-containing compound (A) can be more effectively promoted. As a result, the pattern rectangularity can be improved.

As the metal compound precursor (1), a metal halide compound is preferable, and isopropyltin trichloride or benzyltin trichloride is more preferable.

Examples of the method for performing a hydrolysis condensation reaction on the metal compound precursor (1) include a method in which the metal compound precursor (1) is stirred in water or a solvent containing water in the presence of a base such as tetramethylammonium hydroxide, which is used as necessary. In this case, another compound having a hydrolyzable group may be added, as necessary. The lower limit of the amount of water used in the hydrolysis condensation reaction is preferably 0.2 times mol, more preferably 1 time mol, and still more preferably 3 times mol, in the number of moles, based on the hydrolyzable group of the metal compound precursor (1) and the like. By setting the amount of water in the hydrolysis condensation reaction within the above range, the metal-containing compound (A) can be efficiently obtained.

In the synthesis reaction of the metal-containing compound (A), in addition to the metal compound precursor (1), a compound capable of serving as a multidentate ligand represented by L^{A} in the compound of the formula (4), a compound capable of serving as a bridging ligand, or the like may be added. Examples of the compound capable of serving as a bridging ligand include compounds having two or more groups capable of serving as a ligand, such as a hydroxy group, an isocyanate group, an amino group, an ester group, and an amide group.

In the synthesis reaction of the metal-containing compound (A), the lower limit of the temperature is preferably 0° C., and more preferably 10° C. The upper limit of the temperature is preferably 150° C., more preferably 100° C., and still more preferably 50° C.

In the synthesis reaction of the metal-containing compound (A), the lower limit of the time is preferably 1 minute, more preferably 10 minutes, and still more preferably 1 hour. The upper limit of the time is preferably 100 hours, more preferably 50 hours, still more preferably 24 hours, and particularly preferably 4 hours.

### (Solvent (F))

The solvent (F) is preferably an organic solvent. Specific examples of the organic solvent include those similar to those exemplified as the organic solvent that can be used when vaporizing the compound [A]. In addition, examples of the organic solvent include an alcohol-based solvent, a ketone-based solvent, and a nitrogen-containing solvent.

Examples of the alcohol-based solvents include monoalcohol-based solvents such as methanol, ethanol, n-propanol, isopropanol, 1-butanol, and diacetone alcohol, and polyhydric alcohol-based solvents such as ethylene glycol, and 1, 2-propylene glycol.

Examples of the ketone-based solvents include chain ketone-based solvents such as methyl ethyl ketone, methyl isobutyl ketone, and 2-heptanone; and cyclic ketone-based solvents such as cyclohexanone.

Examples of the nitrogen-containing solvents include chain nitrogen-containing solvents such as N, N-dimethylacetamide, and cyclic nitrogen-containing solvents such as N-methylpyrrolidone.

As the solvent (F), an ether-based solvent is preferable, and propylene glycol monoethyl ether is more preferable.

### (Other Optional Components)

The composition for forming a metal-containing resist film may contain other optional components such as a compound capable of serving as a ligand, and a surfactant, in addition to the metal-containing compound (A) and the solvent (F).

### (Compound Capable of Serving as Ligand)

Examples of the compound capable of serving as a ligand include compounds capable of serving as a multidentate ligand or a bridging ligand, and specifically include the same compounds as the compounds capable of serving as a multidentate ligand or a bridging ligand exemplified in the synthesis method of the metal-containing compound (A).

### (Surfactant)

The surfactant is a component that exhibits an action of improving coatability, striation, and the like. Examples of the surfactant include nonionic surfactants, including polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate. Examples of the product name thereof include KP341 (manufactured by Shin-Etsu Chemical Co., Ltd.), POLYFLOW No. 75, POLYFLOW NO. 95 (both manufactured by Kyoeisha Chemical Co., Ltd.), EFTOP EF301, EFTOP EF303, EFTOP EF352 (all manufactured by Tohkem Products Corporation), MEGAFACE F171, MEGAFACE F173 (both manufactured by DIC), Fluorad FC430, Fluorad FC431 (both manufactured by Sumitomo 3M Limited), ASAHIGUARD AG710, SURFLON S-382, SURFLON SC-101, SURFLON SC-102, SURFLON SC-103, SURFLON SC-104, SURFLON SC-105, SURFLON SC-106 (all manufactured by Asahi Glass Co., Ltd.)

### (Method for Preparing Composition for Forming Metal-Containing Resist Film)

The composition for forming a metal-containing resist film can be prepared, for example, by mixing the metal-containing compound (A), the solvent (F) and, as necessary, other optional components in a prescribed ratio, and preferably filtering the obtained mixture through a membrane filter having a pore size of 0.4 μm or less. The content ratio of the metal-containing compound (A) to components other than the solvent (F) in the composition for forming a metal-containing resist film is preferably 50% by mass or more. The lower limit of the content ratio of the metal-containing compound (A) is more preferably 60% by mass, and still more preferably 70% by mass. On the other hand, the upper limit of the content ratio is preferably 100% by mass, but may be 98% by mass, or may be 95% by mass.

<Method for Forming Coating Film from Composition for Forming Metal-Containing Resist Film>

The method for applying the composition for forming a metal-containing resist film is not particularly limited, and examples thereof include a spin coating method.

To explain this step in more detail, for example, after applying a composition for forming a metal-containing resist film such that the formed metal-containing resist film has a prescribed thickness, pre-baking (hereinafter also referred to as “PB”) is performed to volatilize the solvent in the coating film to form a resist film.

The PB temperature and the PB time may be appropriately determined according to the type and the like of the composition for forming a metal-containing resist film to be used. The lower limit of the PB temperature is preferably 30° C., and more preferably 50° C. The upper limit of the PB temperature is preferably 200° C., and more preferably 150° C. The lower limit of the PB time is preferably 10 seconds, and more preferably 30 seconds. The upper limit of the PB time is preferably 600 seconds, and more preferably 300 seconds.

The lower limit of the average thickness of the metal-containing resist film is preferably 5 nm, more preferably 10 nm, still more preferably 15 nm. The upper limit of the average thickness is preferably 60 nm, more preferably 50 nm, still more preferably 40 nm. The average thickness is measured as described in Examples.

### [Exposing Step]

In this step, the resist film is exposed to radiation.

The radiation for use in the exposure can be appropriately selected depending on the type of the composition for forming a resist film to be used, and the like. Examples of the radiation include electromagnetic waves such as visible rays, ultraviolet rays, far ultraviolet rays, X-rays, and γ-rays, and particle beams such as electron beams, molecular beams, and ion beams. Among them, electron beams or far ultraviolet rays are preferable, electron beams or KrF excimer laser light (wavelength: 248 nm), ArF excimer laser light (wavelength: 193 nm), F2 excimer laser light (wavelength: 157 nm), Kr₂ excimer laser light (wavelength: 147 nm), ArKr excimer laser light (wavelength: 134 nm), or extreme ultraviolet rays (wavelength: 13.5 nm, etc., also referred to as “EUV”) are more preferable, and electron beams or EUV are still more preferable. The exposure conditions can also be appropriately determined depending on the type of the composition for forming a resist film to be used, and the like.

In this step, post-exposure bake (hereinafter also referred to as “PEB”) can be performed in order to improve the performance of the resist film such as resolution, pattern profile, developability, etc. after the exposure. The PEB temperature and PEB time can be appropriately determined according to the type of composition for forming a resist film used. The lower limit of the PEB temperature is preferably 50° C., more preferably 70° C. The upper limit of the PEB temperature is preferably 200° C., more preferably 150° C. The lower limit of the PEB time is preferably 10 seconds, more preferably 30 seconds. The upper limit of the PEB time is preferably 600 seconds, more preferably 300 seconds.

### [Developing Step]

In this step, at least the exposed resist film is developed. The development may be dissolution in a developer or volatilization by heating or decompression depending on the type of the composition for forming a resist film and the like. This makes it possible to form a resist pattern.

Examples of the developer in the case of using the developer include an alkaline aqueous solution (alkaline developer) and an organic solvent-containing solution (organic solvent developer).

The basic solution for alkali development is not particularly limited, and a publicly known basic solution can be used. Examples of the basic solution for alkali development include an alkaline aqueous solution obtained by dissolving at least one alkaline compound such as sodium hydroxide, potassium hydroxide, sodium carbonate, sodium silicate, sodium metasilicate, ammonia water, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo-[5.4.0]-7-undecene, and 1, 5-diazabicyclo-[4.3.0]-5-nonene. Among them, an aqueous TMAH solution is preferable, and a 2.38% by mass aqueous TMAH solution is more preferable.

Examples of the organic solvent developer in the case of performing organic solvent development include the same as those disclosed as the examples of the solvent (F). As the organic solvent developer, an ester-based solvent, an ether-based solvent, an alcohol-based solvent, a ketone-based solvent and/or a hydrocarbon-based solvent is preferable, a ketone-based solvent is more preferable, and 2-heptanone is particularly preferable.

In this step, washing and/or drying may be performed after the development. In addition, etching may be performed using the resist pattern as a mask. Examples of a method for etching include dry etching and wet etching.

### EXAMPLES

Hereinafter, a specific description is made of the present disclosure with reference to Examples, but the present disclosure is not limited to the Examples.

### [Average Thickness of Film]

The average thickness of a film was determined as a value attained by measuring the film thickness at arbitrary nine points at intervals of 5 cm including the center of the thin film formed on a silicon wafer using a spectroscopic ellipsometer (“M2000D” available from J. A. WOOLLAM Co.) and calculating the average value of the film thicknesses.

### <Preparation of Substrate Having Thin Film>

The following compounds were used as raw materials for forming a thin film.

### [Compound [A]]

A-1: Compound represented by formula (A-1)
A-2: Compound represented by formula (A-2)
A-3: Compound represented by formula (A-3)
A-4: Compound represented by formula (A-4)
A-5: Compound represented by formula (A-5)
A-6: Compound represented by formula (A-6)
A-7: Compound represented by formula (A-7)
A-8: Compound represented by formula (A-8)
A-9: Compound represented by formula (A-9)
A-10: Compound represented by formula (A-10)
A-11: Compound represented by formula (A-11)
A-12: Compound represented by formula (A-12)
A-13: Compound represented by formula (A-13)
A-14: Compound represented by formula (A-14)
A-15: Compound represented by formula (A-15)
A-16: Compound represented by formula (A-16)
A-17: Compound represented by formula (A-17)
A-18: Compound represented by formula (A-18)

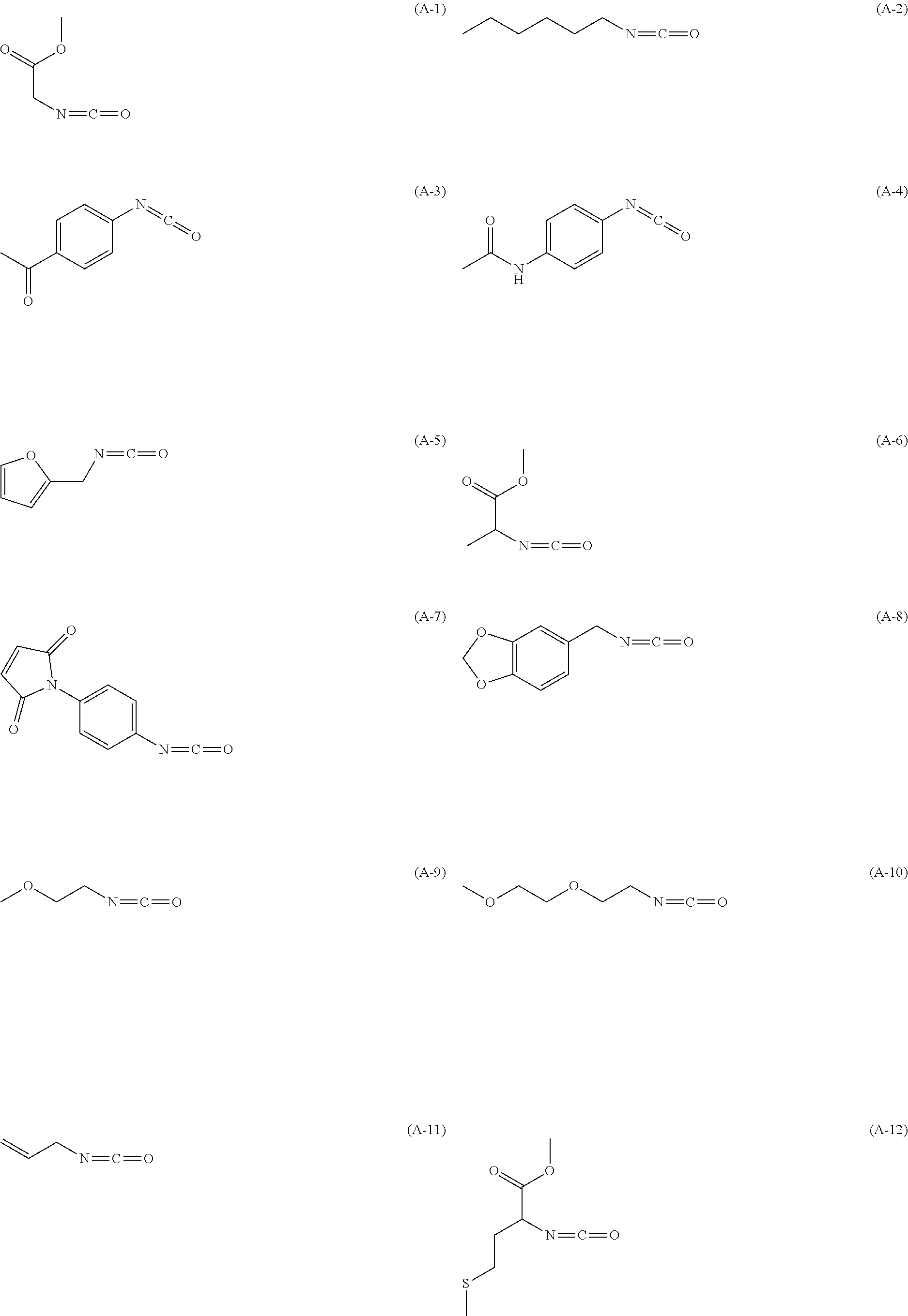

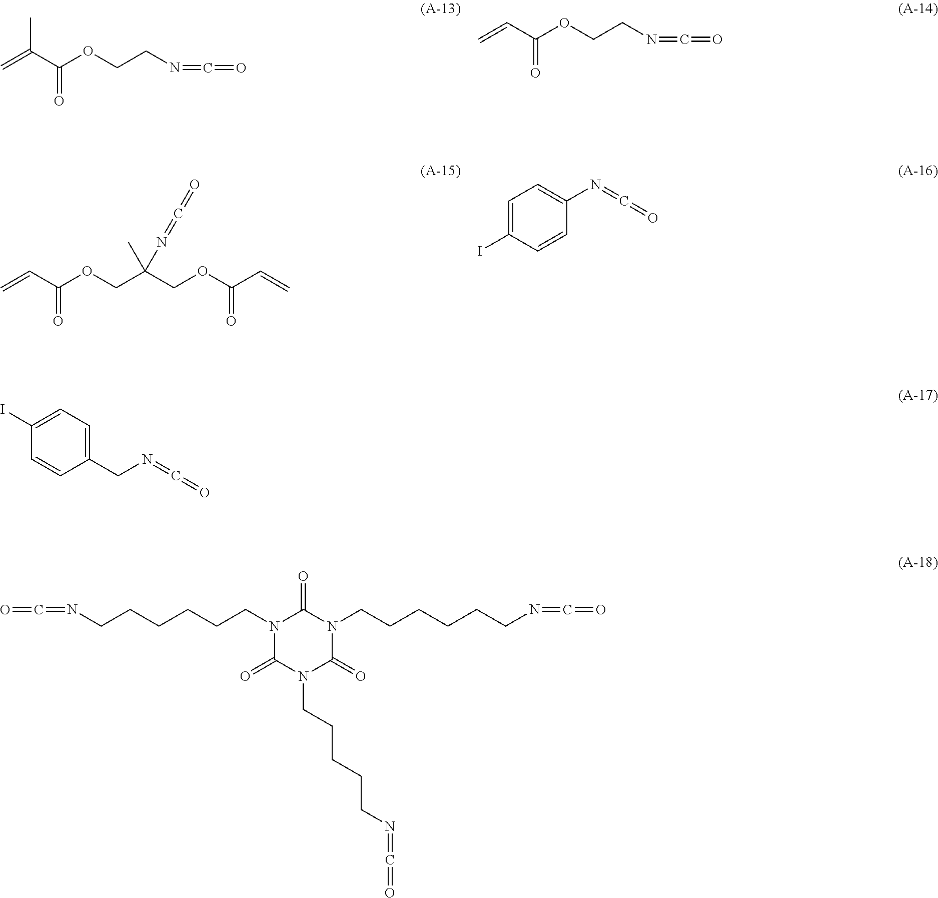

### Example 1-1

A silicon wafer subjected to UV ozone treatment was placed in a chamber. The pressure in the chamber was reduced to 1.0×10⁻² Pa, and the temperature in the chamber was heated to 100° C. The temperature of the container containing the compound (A-1) was heated to 50° C., and the vaporized compound (A-1) was introduced into the chamber and brought into contact with the silicon wafer for 1 minute. Next, the gas in the chamber was discharged, and the substrate was taken out. Finally, the silicon wafer was washed with a mixed solvent of propylene glycol monomethyl ether and propylene glycol monomethyl ether acetate (7:3, volume ratio) to prepare a substrate having a thin film formed thereon (S1-1). The film thickness of the thin film was 1.5 nm. The film thickness of the thin film is also shown in Table 1.

### Example 1-2 to 1-18

Substrates (S1-2) to (S1-6) and (S2-1) to (S2-12) each having a thin film formed thereon were prepared in the same manner as in Example 1 except that the types of the compound [A] shown in the following Table 1 were used.

### Comparative Example 1-1

A substrate (s-1) having a thin film formed thereon was prepared in the same manner as in Example 1-1 except that hexamethyldisilazane (HMDS) was used in place of the compound (A-1), and the temperature in the chamber was 60° C.

TABLE 1

| | Substrate having thin | Compound | Film thickness |
|---|---|---|---|
| | film formed thereon | [A] | (nm) |
| Example 1-1 | S1-1 | A-1 | 1.5 |
| Example 1-2 | S1-2 | A-2 | 2.1 |
| Example 1-3 | S1-3 | A-3 | 1.8 |
| Example 1-4 | S1-4 | A-4 | 1.5 |
| Example 1-5 | S1-5 | A-5 | 1.5 |
| Example 1-6 | S1-6 | A-6 | 1.7 |
| Example 1-7 | S2-1 | A-7 | 1.5 |
| Example 1-8 | S2-2 | A-8 | 1.5 |
| Example 1-9 | S2-3 | A-9 | 1.9 |
| Example 1-10 | S2-4 | A-10 | 1.5 |
| Example 1-11 | S2-5 | A-11 | 2.1 |
| Example 1-12 | S2-6 | A-12 | 2 |
| Example 1-13 | S2-7 | A-13 | 1.5 |
| Example 1-14 | S2-8 | A-14 | 1.7 |
| Example 1-15 | S2-9 | A-15 | 1.7 |
| Example 1-16 | S2-10 | A-16 | 1.9 |
| Example 1-17 | S2-11 | A-17 | 2 |
| Example 1-18 | S2-12 | A-18 | 2.4 |
| Comparative | s-1 | HMDS | 1 |
| Example 1-1 | | | |

### <Evaluation>

Using the substrate having the thin film formed thereon, the resist pattern collapse suppression property was evaluated by the following method. The evaluation results are shown in the following Table 2.

### <Preparation of Resist Composition (R-1)>

A resist composition (R-1) was prepared by mixing 100 parts by mass of a resin (r-1), 20 parts by mass of an acid generator (H-1), 50 mol % of an acid diffusion controlling agent (G-1) with respect to the acid generator (H-1), and 7700 parts by mass of propylene glycol monomethyl ether acetate and 3300 parts by mass of propylene glycol monomethyl ether as solvents, and filtering the mixture through a membrane filter having a pore size of 0.2 μm.

The resin (r-1) was a polymer in which the content ratios of repeating units derived from the following monomer (M-1) and monomer (M-2) were 50 mol % and 50 mol %, respectively, and had an Mw of 6,400 and an Mw/Mn of 1.50. As the acid generator (H-1) and the acid diffusion controlling agent (G-1), the following compounds were used.

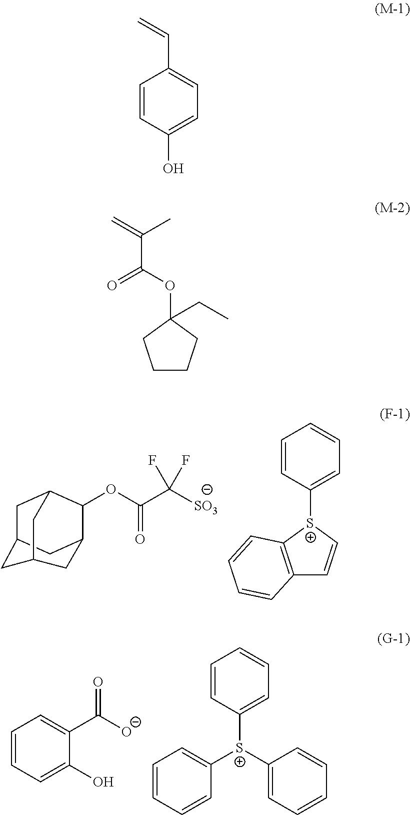

### [Resist Pattern Collapse Suppression Property (EUV Exposure)]

To the substrate having a thin film formed thereon was applied a resist composition (R-1), followed by heating at 130° C. for 60 seconds and then cooling at 23° C. for 30 seconds. As a result, a resist film having an average thickness of 50 nm was formed. Next, the resist film was irradiated with extreme ultraviolet rays using an EUV scanner (“TWINSCAN NXE: 3300B”, available from ASML Co. (NA=0.3; Sigma=0.9; quadrupole illumination, with a 1:1 line and space mask having a line width of 26 nm in terms of a dimension on wafer)). After the irradiation with extreme ultraviolet rays, the substrate was heated at 110° C. for 60 seconds, followed by cooling at 23° C. for 60 seconds. Thereafter, development was performed by a paddle method using a 2.38% by mass aqueous tetramethylammonium hydroxide solution (20° C. to 25° C.), followed by washing with water and drying, thereby affording a substrate for evaluation on which a line and space resist pattern was formed having a line pattern having a line width of 26 nm formed thereon. A scanning electron microscope (“SU8220” available from Hitachi High-Technologies Corporation) was used for length measurement and observation of the resist pattern of the substrate for evaluation. The resist pattern collapse suppression property was evaluated as “A” (good) when there was no resist pattern collapse and the cross-sectional shape of the pattern was rectangular, and evaluated as “B” (poor) when there was a resist pattern collapse.

TABLE 2

| | Substrate having | | Resist pattern |
|---|---|---|---|
| | thin film formed | Resist | collapse suppression |
| | thereon | composition | property |
| Example 2-1 | S1-1 | R-1 | A |
| Example 2-2 | S1-2 | R-1 | A |
| Example 2-3 | S1-3 | R-1 | A |
| Example 2-4 | S1-4 | R-1 | A |
| Comparative | s-1 | R-1 | B |
| Example 2-1 | | | |

### <Evaluation>

Using the substrate having the thin film formed thereon, the resist pattern collapse suppression property was evaluated by the following method. The evaluation results are shown in the following Table 3.

### <Preparation of Resist Composition (R-2)>

### [Synthesis of Compound]

The compound (S-1) to be used for the preparation of the resist composition (R-2) was synthesized by the following procedure. Into a reaction vessel, 6.5 parts by mass of isopropyltin trichloride were added while stirring 150 mL of a 0.5 N aqueous sodium hydroxide solution, and the reaction was carried out for 2 hours. The precipitate formed was collected by filtration, washed twice with 50 parts by mass of water, and then dried to obtain a compound (S-1). The compound (S-1) was an oxidized hydroxide product of a hydrolysate of isopropyltin trichloride (the oxidized hydroxide product contained i-PrSnO_{(3/2-x/2)} (OH)ₓ (0<x<3) as a structural unit).

Mixed were 2 parts by mass of the compound (S-1) synthesized above and 98 parts by mass of propylene glycol monoethyl ether, and the obtained mixture was subjected to removal of residual water with activated 4 Å molecular sieve, and then filtered through a filter having a pore size of 0.2 μm. Thus, a resist composition (R-2) was prepared.

### [Resist Pattern Collapse Suppression Property (EUV Exposure)]

The substrate having a thin film formed thereon was coated with the resist composition (R-2) by the spin coating method using a spin coater, and after a lapse of a prescribed time, heated at 90° C. for 60 seconds, and then cooled at 23° C. for 30 seconds. As a result, a resist film having an average thickness of 35 nm was formed. The resist film was exposed to light using an EUV scanner (“TWINSCAN NXE: 3300B”, available from ASML Co. (NA=0.3; Sigma=0.9; quadrupole illumination, with a 1:1 line and space mask having a line width of 16 nm in terms of a dimension on wafer)). After the exposure, the substrate was heated at 110° C. for 60 seconds, and subsequently cooled at 23° C. for 60 seconds. Thereafter, development was performed by a paddle method using 2-heptanone (20 to 25° C.), followed by drying, thereby affording a substrate for evaluation on which a resist pattern having a line width of 16 nm and a line and space ratio of 1:1 was formed. A scanning electron microscope (“CG-6300” available from Hitachi High-Tech Corporation) was used for length measurement and observation of the resist pattern of the substrate for evaluation. The resist pattern collapse suppression property was evaluated as “A” (good) when there was no resist pattern collapse and the cross-sectional shape of the pattern was rectangular, and evaluated as “B” (poor) when there was a resist pattern collapse.

TABLE 3

| | Substrate having | | Resist pattern |
|---|---|---|---|
| | thin film formed | Resist | collapse suppression |
| | thereon | composition | property |
| Example 3-1 | S2-1 | R-2 | A |
| Example 3-2 | S2-2 | R-2 | A |
| Example 3-3 | S2-4 | R-2 | A |
| Example 3-4 | S2-7 | R-2 | A |
| Example 3-5 | S2-10 | R-2 | A |
| Comparative | s-1 | R-2 | B |
| Example 3-1 | | | |

As can be seen from the results of Tables 2 and 3, the substrates each having a thin film formed thereon of Examples were superior in resist pattern collapse suppression property to the substrates of Comparative Examples.

The substrate for manufacturing a semiconductor of the present disclosure is excellent in resist pattern collapse suppression property. According to the method for manufacturing a substrate for manufacturing a semiconductor of the present disclosure, it is possible to manufacture a substrate for manufacturing a semiconductor excellent in resist pattern collapse suppression property. According to the method for manufacturing a semiconductor substrate of the present disclosure, since the substrate for manufacturing a semiconductor capable of exhibiting excellent pattern collapse suppression property is used, a high-quality semiconductor substrate can be efficiently manufactured. Accordingly, the substrate and methods can suitably be used for, for example, manufacturing semiconductor devices expected to be further microfabricated in the future.

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A substrate comprising:
a substrate having a thin film on a surface thereof,
wherein the thin film comprises a group derived from a compound represented by formula (1): 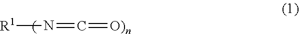
wherein in the formula (1),
R¹ is an n-valent organic group having 1 to 40 carbon atoms, and
n is an integer of 1 to 4.

2. The substrate according to claim 1, wherein the thin film is produced by a gas phase reaction between the compound represented by the formula (1) and the substrate.

3. The substrate according to claim 1, wherein the organic group comprises a hetero atom or an unsaturated bond.

4. The substrate according to claim 1, wherein a film thickness of the thin film is 2 nm or less.

5. The substrate according to claim 1, wherein the substrate is suitable for EUV lithography.

6. A method for manufacturing a substrate for manufacturing a semiconductor, comprising:
bringing a substrate and a compound represented by formula (1) into contact to produce the substrate for manufacturing a semiconductor: 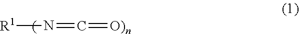
wherein in the formula (1),
R¹ is an n-valent organic group having 1 to 40 carbon atoms, and
n is an integer of 1 to 4.

7. The method according to claim 6, further comprising:
vaporizing the compound represented by the formula (1) before bringing the substrate and the compound represented by formula (1) into contact.

8. A method for manufacturing a semiconductor substrate, comprising:
forming a resist film on the substrate for manufacturing a semiconductor obtained by the method according to claim 6;
exposing the resist film to radiation; and
developing at least the exposed resist film.

9. The method according to claim 8, wherein the radiation is extreme ultraviolet rays.

10. The method according to claim 8, wherein the resist film comprises a metal.

11. The method according to claim 10, wherein the resist film is formed from a composition which comprises a metal-containing compound and a solvent, and a content ratio of the metal-containing compound to components other than the solvent in the composition is 50% by mass or more.
